(19) United States
(12) Patent Application Publication
(10) Pub. No.: US 2022/0384517 A1
(43) Pub. Date: Dec. 1, 2022

(54) MONOLITHICALLY AND HETEROGENEOUSLY INTEGRATED MICRO-LIGHT-EMITTING DIODE (MICROLED) DISPLAY CHIP AND PREPARATION METHOD THEREOF

(71) Applicant: NANJING UNIVERSITY, Nanjing (CN)

(72) Inventors: Xinran WANG, Nanjing (CN); Bin LIU, Nanjing (CN); Wanqing MENG, Nanjing (CN); Feifan XU, Nanjing (CN); Zhihao YU, Nanjing (CN); Tao TAO, Nanjing (CN)

(73) Assignee: NANJING UNIVERSITY, Nanjing (CN)

(21) Appl. No.: 17/555,538

(22) Filed: Dec. 20, 2021

(30) Foreign Application Priority Data
May 31, 2021 (CN) 202110601695.9

(51) Int. Cl. H01L 27/15

(52) U.S. Cl. CPC H01L 27/156

(57) ABSTRACT

A monolithically and heterogeneously integrated micro-light-emitting diode (microLED) display chip includes the following parts from bottom to top: an LED epitaxial wafer, an isolation layer, a two-dimensional (2D) thin-film transistor (TFT) drive array. The LED epitaxial wafer is provided with a microLED column display array. The 2D TFT drive array is connected to the microLED column display array through a metal column array. A top-gate field-effect transistor (FET) or a back-gate FET is used as a 2D TFT. A channel layer of the 2D TFT is made of a 2D layered material. The vertical monolithic heterogeneous integration is achieved through a drive circuit defined by a microLED column array on the epitaxial wafer and the 2D TFT matrix. A preparation method of the monolithically and heterogeneously integrated microLED display chip is provided.

### CROSS REFERENCE TO THE RELATED APPLICATIONS

This application is based upon and claims priority to Chinese Patent Application No. 202110601695.9, filed on May 31, 2021, the entire contents of which are incorporated herein by reference.

### TECHNICAL FIELD

The present disclosure relates to a monolithically and heterogeneously integrated micro-light-emitting diode (microLED) display chip and a preparation method thereof, and belongs to the technical field of microLED displays.

### BACKGROUND

Nitride semiconductor light-emitting diodes (LEDs) have changed the development trajectory of the solid-state lighting industry since its debut, and now have become a multi-billion-dollar industry. In recent years, microLED devices based on nitride semiconductor LEDs have brought new opportunities to the industry. Specifically, microLED devices can be used in fields such as high-resolution microdisplays for augmented reality (AR) and virtual reality (VR), visible light communications and biomedical probes. At present, gallium nitride (GaN)-based microLEDs can provide extremely high brightness exceeding 10⁷ cd/m², nanosecond response time and luminous efficiency as high as 60%, so that microLEDs are likely to become the strongest optional display device for the next generation. In order to satisfy the high resolution and human-computer interaction requirements for future intelligent display and information display, next-generation displays are required to achieve micron pixel size, ultra-high brightness and multi-functional heterogeneous integration. At present, bounded by the mobility of amorphous silicon (a-Si) and indium gallium zinc oxide (IGZO) in the mainstream thin-film transistor (TFT) technology, the driving current cannot be applied to ultra-small GaN-based microLEDs. Besides, low-temperature polycrystalline silicon (LTPS) technology involves high-energy processes such as laser annealing and ion implantation, which seriously affects the light-emitting characteristics of microLEDs. In addition, the TFT backplane technology and the microLED integration technology typically rely on mass transfers, which makes it hard to control the yield and cost and therefore hard to achieve mass production. High-performance TFT backplane technology and low-temperature monolithic heterogeneous integration technology are currently the bottlenecks in the development of microLEDs.

Two-dimensional (2D) semiconductor materials mainly including transition metal sulfides have become a powerful competitor for the next generation of information materials due to their atomic-level thickness, high mobility and wide band gap. Taking MoS₂ as an example, 2D semiconductor materials as new-generation TFT channel materials have the following notable features. (1) Compared with traditional TFT technology, the mobility of crystalline (single crystal) materials is greater than 100 cm²/Vs, which is much higher than that of amorphous (polycrystalline) materials, and the maximum saturation current is also much larger than the traditional TFT technology. Therefore, the crystalline (single crystal) materials can drive microLEDs at low voltages so as to reduce the power consumption of the backplane. In addition, their atomic-level thickness ensures extremely low standby current leakage, further reducing static power consumption. (2) A variety of 2D semiconductor materials, including MoS₂, can achieve wafer-level size material synthesis through chemical vapor deposition (CVD), and expand the film size without a hitch. (3) 2D semiconductor materials are assembled through van der Waals interaction, and can be transferred to any substrate at room temperature, enabling the integration with the mainstream semiconductor technology by means of backend-of-the-line (BEOL) processes. (4) The 2D semiconductor materials having the atomic-level thickness possess excellent flexibility and optical transparency, which provides new opportunities for their applications in advanced displays.

### SUMMARY

An objective of the present disclosure is to provide a monolithically and heterogeneously integrated micro-light-emitting diode (microLED) display chip, which features high resolution, large driving current (simply large current density, and the actual current depends on the physical size), high brightness and low voltage.

The objective of the present disclosure is achieved by the following technical solution.

A monolithically and heterogeneously integrated microLED display chip includes the following parts from bottom to top:

an LED epitaxial wafer, where the LED epitaxial wafer is provided with a microLED column display array; and the LED epitaxial wafer may adopt a conventional commercial LED chip, which may be provided with a silicon substrate or a sapphire substrate and may have various wavelengths;

an isolation layer; and

a two-dimensional (2D) thin-film transistor (TFT) drive array;

where, the 2D TFT drive array is connected to the microLED column display array through a metal column array; and

a top-gate field-effect transistor (FET) or a back-gate FET is used as a 2D TFT, which is provided with a channel layer made of a 2D layered material, where, in a specific implementation, a p-type electrode array and an n-type electrode are usually vapor-deposited on the LED epitaxial wafer, and the 2D TFT drive array is connected to a p-type electrode through a metal column to drive a microLED column to emit light or not.

Preferably, the 2D TFT may sequentially include the following parts from bottom to top:

a back-gate electrode;

a gate dielectric layer;

the channel layer made of a 2D layered material; and

a source electrode and a drain electrode located on two sides of the channel layer, where a metal column connected to a microLED column is connected to the drain electrode.

Preferably, the 2D TFT may sequentially include the following parts from bottom to top:

a channel layer made of a 2D layered material;

a source electrode and a drain electrode located on two sides of the channel layer, where a metal column connected to a microLED column is connected to the drain electrode;

a gate dielectric layer; and

a top-gate electrode.

Preferably, the 2D layered material may be black phosphorus (BP) or a layered transition metal compound.

Preferably, the 2D layered material may be MoS₂ or WS₂.

Preferably, the isolation layer may be an insulating dielectric layer.

Preferably, the 2D TFT drive array and the microLED column display array may be stacked in a staggered manner to avoid blocking light emitted by the microLED column.

The present disclosure further provides a preparation method of the monolithically and heterogeneously integrated microLED display chip, which achieves large-scale heterogeneous integration without mass transfer at room temperature, and includes the following steps:

1) patterning a superlattice epitaxial wafer by means of semiconductor processing, etching to form the microLED column array, and vapor-depositing electrodes to form the LED epitaxial wafer with a P-type electrode and an N-type electrode, where this process is a conventional semiconductor process, achieved by a photolithography technology;

2) applying the isolation layer onto the LED epitaxial wafer formed with the microLED column display array until the microLED column is no longer exposed;

3) preparing the back-gate electrode and the gate dielectric layer in sequence on a surface of the isolation layer;

4) forming, by a photolithography process, a hole deep to the P-type electrode on a surface of a device obtained in step 3), and depositing the metal column in the hole as an anode of an LED;

5) peeling off a crystal film formed by a 2D layered material, and transferring the crystal film to the surface of the device; and

6) etching the crystal film to form an array structure corresponding to the microLED column display array, and depositing the source electrode and the drain electrode on two sides of the crystal film, where the drain electrode is electrically connected to the metal column deposited in a channel.

The present disclosure further provides another preparation method of the monolithically and heterogeneously integrated microLED display chip, which includes the following steps:

1) patterning a superlattice epitaxial wafer by means of semiconductor processing, etching to form the microLED column array, and vapor-depositing electrodes to form the LED epitaxial wafer with a P-type electrode and an N-type electrode;

2) applying the isolation layer onto the superlattice epitaxial wafer formed with the microLED column display array until the microLED column is no longer exposed;

3) forming, by a photolithography process, a hole deep to the microLED column on a surface of a device obtained in step 3), and depositing the metal column in the hole as an anode of an LED;

4) peeling off a crystal film formed by a 2D layered material, and transferring the crystal film to the surface of the device;

5) etching the crystal film to form an array structure corresponding to the microLED column display array, and depositing the source electrode and the drain electrode on two sides of the crystal film, where the drain electrode is electrically connected to the metal column deposited in a channel; and

6) preparing the gate dielectric layer and the top-gate electrode in sequence on a surface of the isolation layer, thereby completing the preparation of the device.

The present disclosure has the following beneficial effects:

(1) All processes in the present disclosure can be completed at a temperature lower than 250° C., avoiding the high-energy annealing and ion implantation required by the existing processes, thereby improving the device yield and achieving industrialization.

(2) The method of the present disclosure achieves a monolithic heterogeneous integration process, and achieves the one-time on-chip integration of the backend-of-the-line (BEOL) process and the front-end display chip. The present disclosure avoids the mass transfer in the traditional microLED display chip preparation process, and achieves large-scale heterogeneous integration without mass transfer at room temperature.

(3) The present disclosure can achieve a transistor size as low as sub-micron, and can achieve ultra-high resolution (1,000 PPI or more) drive matrix integration.

(4) The present disclosure can achieve a maximum current density of the transistor exceeding 200 μA/μm, which is significantly higher than that in the current matrix drive scheme.

(5) The present disclosure is suitable for heterogeneous integration of flexible substrates, and achieves a light transmittance of more than 90% by using a single-layer 2D semiconductor, which is suitable for a transparent display process.

(6) The present disclosure can prepare a chip featuring high resolution, high driving current, high brightness and low voltage, which has broad application prospects in the future ultra-high resolution, ultra-high brightness display, and visible light communication.

### BRIEF DESCRIPTION OF THE DRAWINGS

FIG. 1 is a micrograph of a patterned micro-light-emitting diode (microLED) pixel array in Embodiment 1;

FIG. 2A is a micrograph of a MoS₂ back-gate transistor drive matrix and FIG. 2B is a micrograph of a microLED array, wherein the MoS₂ back-gate transistor drive matrix and the microLED array are monolithically and heterogeneously integrated by means of a backend-of-the-line (BEOL) process in Embodiment 1;

FIG. 3 is a micrograph of a single MoS₂ back-gate transistor array and a microLED array that are monolithically and heterogeneously integrated by means of a BEOL process in Embodiment 1;

FIG. 4 is a scanning electron microscope (SEM) image of a section of the MoS₂ back-gate transistor drive matrix and the microLED array that are monolithically and heterogeneously integrated by means of a BEOL process in Embodiment 1;

FIG. 5 is a view illustrating a structure of the MoS₂ back-gate transistor drive matrix and the microLED array that are monolithically and heterogeneously integrated by means of a BEOL process in Embodiment 1;

FIG. 6 is a transfer characteristic curve of a MoS₂ back-gate transistor in Embodiment 1;

FIG. 7 is an output characteristic curve of the MoS₂ back-gate transistor in Embodiment 1;

FIG. 8 is an electrical characteristic curve of the single MoS₂ back-gate transistor array and the microLED array that are monolithically and heterogeneously integrated by means of a BEOL process in Embodiment 1;

FIG. 9 is a view illustrating a WS₂ top-gate transistor drive matrix and a microLED array that are monolithically and heterogeneously integrated by means of a BEOL process in Embodiment 2;

FIG. 10 is a section view of a microLED display chip fabricated by monolithic heterogeneous integration by means of a BEOL process in Embodiment 2; and

FIG. 11 is a view illustrating a structure of a microLED display array chip.

### DETAILED DESCRIPTION OF THE EMBODIMENTS

The technical solutions in the embodiments of the present disclosure are described clearly and completely below with reference to the drawings in the embodiments of the present disclosure. Apparently, the described embodiments are merely a part rather than all of the embodiments of the present disclosure. All other embodiments obtained by those of ordinary skill in the art based on the embodiments of the present disclosure without creative efforts should fall within the protection scope of the present disclosure.

### Embodiment 1

In this embodiment, preparation is carried out based on a single-layer MoS₂ back-gate transistor drive matrix and a micro-light-emitting diode (microLED) chip that are monolithically and heterogeneously integrated by means of a backend-of-the-line (BEOL) process, and performance testing is also carried.

A preparation process includes:

(1) Spin-coated glass is prepared on a surface of a microLED display array chip by a spin coater first at 500 rpm for 10 s and then at 8,000 rpm for 60 s. The spin-coated chip is placed on a heating stage to be slowly heated up to a target temperature of 250° C. for drying and curing.

The chip is placed in an atomic layer deposition (ALD) chamber to deposit a flat surface layer. The chamber is vacuum-pumped and heated to 150° C. Trimethyl aluminum is used as a metal source, and water is used as an oxidation source. The pulse time is respectively set to 25 ms and 20 ms, and the number of cycles is set to 200. Alumina is grown to a thickness of about 20 nm. The cleaning time between two pulses is 30 s.

(2) A photoresist is spin-coated on the surface of the chip and dried. A central area of the chip is exposed by an ultraviolet lithography machine, and the exposed area is developed by a developer.

After development, the chip is placed in an electron beam evaporation (EBE) chamber. The EBE chamber is vacuum-pumped to 1×10⁻⁶ Torr, and 5 nm titanium and 15 nm palladium are successively vapor-deposited at 0.2 A/s as a back-gate metal. The photoresist is removed by acetone, leaving the vapor-deposited metal area.

The chip is placed in an ALD chamber to deposit a gate dielectric layer. The chamber is vacuum-pumped and heated to 150° C. Trimethyl aluminum is used as a metal source, and water is used as an oxidation source. The pulse time is respectively set to 25 ms and 20 ms, and the number of cycles is set to 200. Alumina is grown to a thickness of about 20 nm. The cleaning time between two pulses is 30 s.

(3) A photoresist is spin-coated on the surface of the chip and dried. An upper area of the chip is exposed by an ultraviolet lithography machine, and the exposed area is developed by a developer. After development, the chip is placed in a reactive ion-beam etching (RIBE) chamber. The etching chamber is vacuum-pumped to 2 Pa. The etching power is set to 100 watts, and a mixture of carbon tetrafluoride/oxygen gas is introduced at 50 sccm/5 sccm each. The etching time is set to 15 min, and the chip is etched to a p-type electrode.

After etching, the chip is placed in an EBE chamber. The EBE chamber is vacuum-pumped to 1×10⁻⁶ Torr, and 50 nm titanium, 50 nm aluminum and 50 nm nickel are successively vapor-deposited at 0.2 A/s as a metal column. The photoresist is removed by acetone for further use.

(4) A polymethyl methacrylate solution is spin-coated on a single-layer molybdenum disulfide film, obtained by means of CVD, first at 500 rpm for 10 s and then at 2,000 rpm for 60 s. A heating stage is preheated to 150°, and the spin-coated chip is placed on the heating stage for drying and curing for 15 min. A polydimethylsiloxane film is attached to the cured polymethyl methacrylate film, and a substrate is placed in a saturated potassium hydroxide solution to slowly peel the single-layer molybdenum disulfide from the substrate.

The peeled film is attached to the chip after step (3), and the chip is placed on a heating stage to be slowly heated to a target temperature of 100° C. In this way, the molybdenum disulfide is attached to the chip, and the polydimethylsiloxane film is separated from the polymethyl methacrylate film.

(5) The polymethyl methacrylate film is exposed at a position above the back-gate metal by an electron beam (E-beam) lithography machine, with an E-beam dose of 250 μC/cm², and the exposed area is developed with a developer. After development, the chip is placed in an RIBE chamber. The etching chamber is vacuum-pumped to 2 Pa. The etching power is set to 100 watts, and a mixture of carbon tetrafluoride/oxygen gas is introduced at 50 sccm each. The etching time is set to 10 s. The size of molybdenum sulfide after etching is 5 μm×10 μm.

(6) A photoresist is spin-coated on the surface of the chip and dried. Source and drain electrode areas are exposed in the molybdenum disulfide area by an ultraviolet lithography machine, where a source electrode and a drain electrode are spaced 1 μm apart. The source electrode area is in communication with a hole etched in step (3). The exposed area is developed by a developer. After development, the chip is placed in an EBE chamber. The EBE chamber is vacuum-pumped to 1×10⁻⁶ Torr, and 5 nm titanium and 50 nm palladium are successively vapor-deposited at 0.2 A/s as source and drain metal electrodes. The drain metal electrode is connected to the metal column prepared in step (3). The photoresist is removed by acetone, leaving the vapor-deposited metal area.

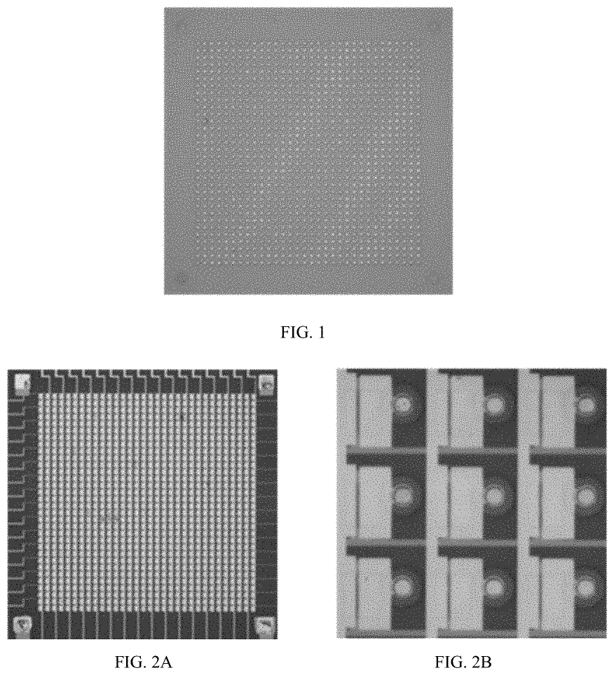

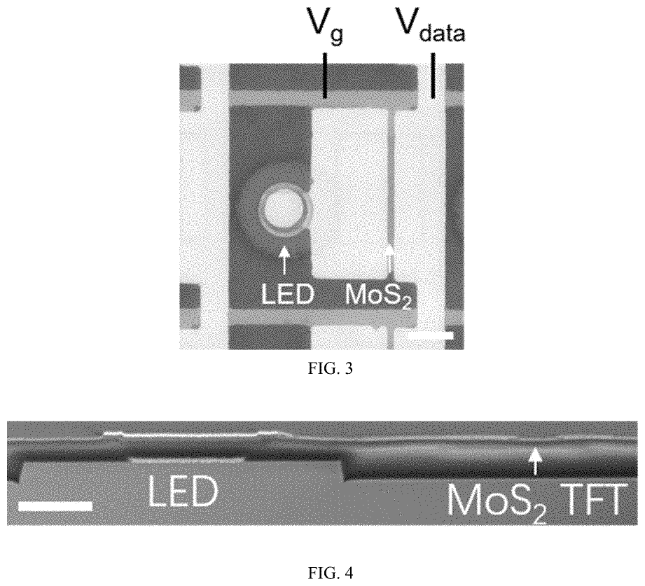

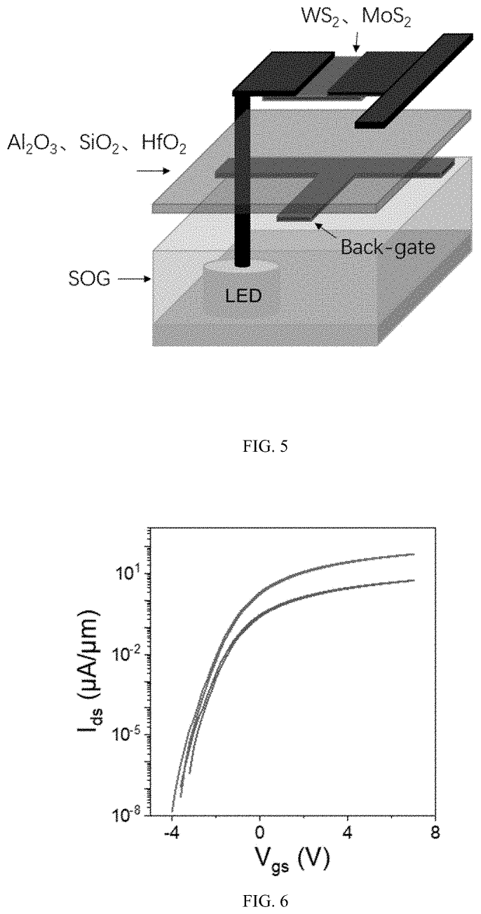

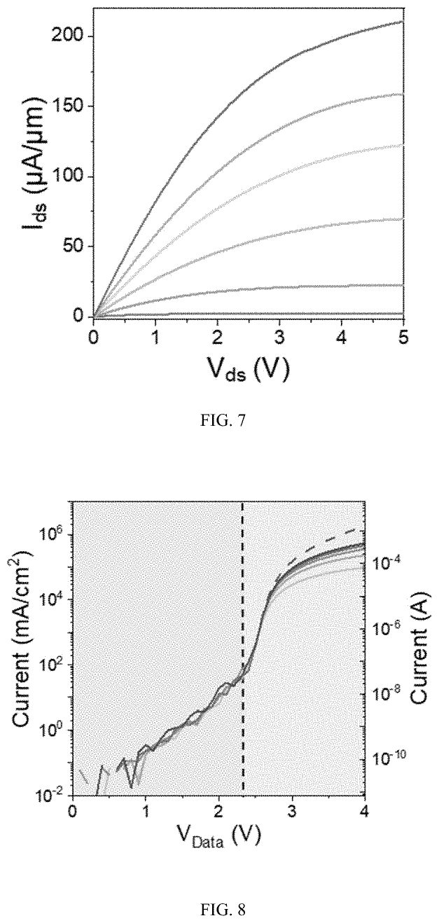

FIG. 1 is a micrograph of a patterned microLED pixel array in Embodiment 1; FIG. 2 is a micrograph of a MoS₂ back-gate transistor drive matrix and a microLED array that are monolithically and heterogeneously integrated by means of a BEOL process in Embodiment 1; FIG. 2 is a micrograph of a single MoS₂ back-gate transistor array and a microLED array that are monolithically and heterogeneously integrated by means of a BEOL process in Embodiment 1; FIG. 4 is a scanning electron microscope (SEM) image of a section of the MoS₂ back-gate transistor drive matrix and the microLED array that are monolithically and heterogeneously integrated by means of a BEOL process in Embodiment 1; FIG. 5 is a view illustrating a structure of the MoS2 back-gate transistor drive matrix and the microLED array that are monolithically and heterogeneously integrated by means of a BEOL process in Embodiment 1; FIG. 6 is a transfer characteristic curve of a MoS₂ back-gate transistor in Embodiment 1; FIG. 7 is an output characteristic curve of the MoS₂ back-gate transistor in Embodiment 1; and FIG. 8 is an electrical characteristic curve of the single MoS₂ back-gate transistor array and the microLED array that are monolithically and heterogeneously integrated by means of a BEOL process in Embodiment 1.

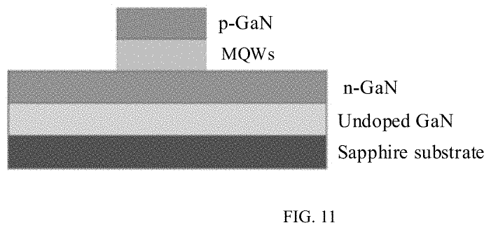

The microLED display array chip can adopt the structure shown in FIG. 11. In this embodiment, it is a 32*32 array chip, and the physical size of a single LED is 10 μm. Chips with other structures can also be used, such as square and hexagonal structures, and the array structure can also be arranged in other ways. The physical size is adjustable. Generally speaking, this technology is not required for large-sized LEDs. The traditional TFT process has advantages for small-sized LEDs.

The microLED display array chip can also adopt other structures disclosed in the art, for example, a reflective layer, a buffer layer, etc. can be added. Other auxiliary structures can be compatible with this structure.

In this embodiment, a photolithography process is adopted, and the channel area is 1 μm wide and 10 μm long to achieve a resolution of 1,280 PPI. The photolithography process has low cost and is suitable for industrialization. If a more advanced photolithography process or E-beam lithography is used, a sub-micron size and a resolution of 5,000 and above can be achieved.

### Embodiment 2

In this embodiment, preparation is carried out based on a single-layer WS₂ a top-gate transistor drive matrix and a microLED chip that are monolithically and heterogeneously integrated by means of a BEOL process, and performance testing is also carried.

A preparation process includes:

(1) Spin-coated glass is prepared on a surface of a microLED display array chip by a spin coater first at 500 rpm for 10 s and then at 8,000 rpm for 60 s. The spin-coated chip is placed on a heating stage to be slowly heated up to a target temperature of 250° C. for drying and curing.

The chip is placed in an ALD chamber to deposit a flat surface layer. The chamber is vacuum-pumped and heated to 150° C. Trimethyl aluminum is used as a metal source, and water is used as an oxidation source. The pulse time is respectively set to 25 ms and 20 ms, and the number of cycles is set to 200. Alumina is grown to a thickness of about 20 nm. The cleaning time between two pulses is 30 s.

(2) A photoresist is spin-coated on the surface of the chip and dried. An upper area of the chip is exposed by an ultraviolet lithography machine, and the exposed area is developed by a developer. After development, the chip is placed in an RIBE chamber. The etching chamber is vacuum-pumped to 2 Pa. The etching power is set to 100 watts, and a mixture of carbon tetrafluoride/oxygen gas is introduced at 50 sccm/5 sccm each. The etching time is set to 15 min, and the chip is etched to a p-type electrode.

After etching, the chip is placed in an EBE chamber. The EBE chamber is vacuum-pumped to 1×10⁻⁶ Torr, and 50 nm titanium, 50 nm aluminum and 50 nm nickel are successively vapor-deposited at 0.2 A/s as a metal column. The photoresist is removed by acetone for further use.

(3) A polymethyl methacrylate solution is spin-coated on a single-layer WS₂ film, obtained by means of CVD, first at 500 rpm for 10 s and then at 2,000 rpm for 60 s. A heating stage is preheated to 150°, and the spin-coated chip is placed on the heating stage for drying and curing for 15 min. A polydimethylsiloxane film is attached to the cured polymethyl methacrylate film, and a substrate is placed in a saturated potassium hydroxide solution to slowly peel the single-layer WS₂ from the substrate.

The peeled film is attached to the chip after step (2), and the chip is placed on a heating stage to be slowly heated to a target temperature of 100° C. In this way, the WS₂ is attached to the chip, and the polydimethylsiloxane film is separated from the polymethyl methacrylate film.

(4) The polymethyl methacrylate film is exposed at a position above the back-gate metal by an E-beam lithography machine, with an E-beam dose of 250 μC/cm², and the exposed area is developed with a developer. After development, the chip is placed in an RIBE chamber. The etching chamber is vacuum-pumped to 2 Pa. The etching power is set to 100 watts, and a mixture of carbon tetrafluoride/oxygen gas is introduced at 50 sccm each. The etching time is set to 10 s. The size of molybdenum sulfide after etching is 5 μm×10 μm.

(5) A photoresist is spin-coated on the surface of the chip and dried. Source and drain electrode areas are exposed in the WS₂ area by an ultraviolet lithography machine, where a source electrode and a drain electrode are spaced 1 μm apart. The source electrode area is in communication with a hole etched in step (2). The exposed area is developed by a developer. After development, the chip is placed in an EBE chamber. The EBE chamber is vacuum-pumped to 1×10⁻⁶ Torr, and 5 nm titanium and 50 nm palladium are successively vapor-deposited at 0.2 A/s as source and drain metal electrodes. The drain metal electrode is connected to the metal column prepared in step (3). The photoresist is removed by acetone, leaving the vapor-deposited metal area.

(6) The chip is placed in an ALD chamber to deposit a gate dielectric layer. The chamber is vacuum-pumped and heated to 150° C. Trimethyl aluminum is used as a metal source, and water is used as an oxidation source. The pulse time is respectively set to 25 ms and 20 ms, and the number of cycles is set to 200. Alumina is grown to a thickness of about 20 nm. The cleaning time between two pulses is 30 s.

(7) A photoresist is spin-coated on the surface of the chip and dried. A central area of the chip is exposed by an ultraviolet lithography machine, and the exposed area is developed by a developer.

After development, the chip is placed in an EBE chamber. The EBE chamber is vacuum-pumped to 1×10⁻⁶ Torr, and 5 nm titanium and 15 nm palladium are successively vapor-deposited at 0.2 A/s as a top-gate metal. The photoresist is removed by acetone, leaving the vapor-deposited metal area.

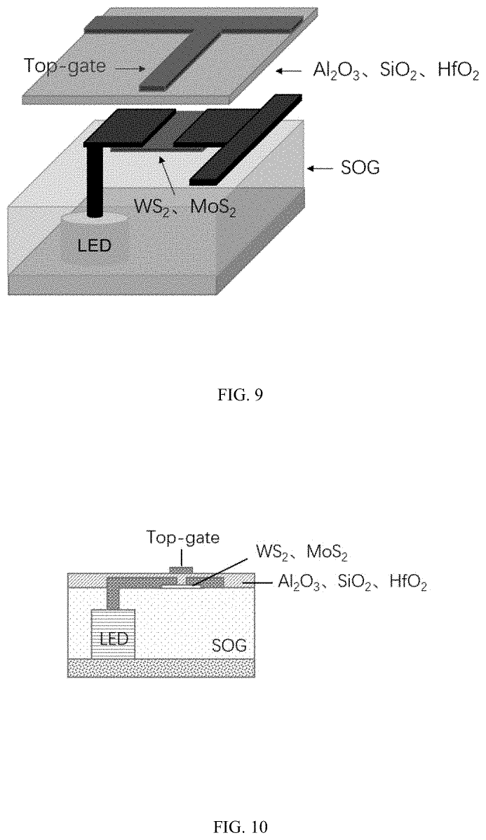

FIGS. 9 and 10 illustrate the structure of this embodiment. The above embodiments are preferred implementations of the present disclosure, but the implementations of the present disclosure are not limited to the above embodiments. Changes, retouches, replacements, combinations and simplifications made without departing from the spiritual essence and principle of the present disclosure should be equivalent substitution manners, and should all be included in the protection scope of the present disclosure.

What is claimed is:

1. A monolithically and heterogeneously integrated micro-light-emitting diode (microLED) display chip, comprising the following parts from bottom to top:
an LED epitaxial wafer, wherein the LED epitaxial wafer is provided with a microLED column display array;
an isolation layer; and
a two-dimensional (2D) thin-film transistor (TFT) drive array;
wherein, the 2D TFT drive array is connected to the microLED column display array through a metal column array; and
a top-gate field-effect transistor (FET) or a back-gate FET is used as a 2D TFT, and a channel layer of the 2D TFT is made of a 2D layered material.

2. The monolithically and heterogeneously integrated microLED display chip according to claim 1, wherein the 2D TFT sequentially comprises the following parts from bottom to top:
a back-gate electrode;
a gate dielectric layer;
the channel layer made of the 2D layered material; and
a source electrode and a drain electrode located on two sides of the channel layer, wherein a metal column connected to a microLED column is connected to the drain electrode.

3. The monolithically and heterogeneously integrated microLED display chip according to claim 1, wherein the 2D TFT sequentially comprises the following parts from bottom to top:
the channel layer made of the 2D layered material;
a source electrode and a drain electrode located on two sides of the channel layer, wherein a metal column connected to a microLED column is connected to the drain electrode;
a gate dielectric layer; and
a top-gate electrode.

4. The monolithically and heterogeneously integrated microLED display chip according to claim 1, wherein the 2D layered material is black phosphorus (BP) or a layered transition metal compound.

5. The monolithically and heterogeneously integrated microLED display chip according to claim 4, wherein the 2D layered material is MoS₂ or WS₂.

6. The monolithically and heterogeneously integrated microLED display chip according to claim 4, wherein the isolation layer is an insulating dielectric layer.

7. The monolithically and heterogeneously integrated microLED display chip according to claim 1, wherein the 2D TFT drive array and the microLED column display array are stacked in a staggered manner to avoid blocking light emitted by the microLED column display array.

8. A preparation method of the monolithically and heterogeneously integrated microLED display chip according to claim 1, wherein the preparation method comprises the following steps:
1) patterning a superlattice epitaxial wafer by a semiconductor processing technology, etching to form the microLED column array, and vapor-depositing electrodes to form the LED epitaxial wafer with a P-type electrode and an N-type electrode;
2) applying the isolation layer onto the LED epitaxial wafer formed with the microLED column display array until microLED columns are no longer exposed;
3) preparing a back-gate electrode and a gate dielectric layer in sequence on a surface of the isolation layer to obtain a device;
4) forming, by a photolithography process, a hole deep to the P-type electrode on a surface of the device, and depositing a metal column in the hole as an anode of an LED;
5) peeling off a crystal film formed by the 2D layered material, and transferring the crystal film to the surface of the device; and
6) etching the crystal film to form an array structure corresponding to the microLED column display array, and depositing a source electrode and a drain electrode on two sides of the crystal film, wherein the drain electrode is electrically connected to the metal column deposited in the hole.

9. A preparation method of the monolithically and heterogeneously integrated microLED display chip according to claim 1, wherein the preparation method comprises the following steps:
1) patterning a superlattice epitaxial wafer by means of a semiconductor processing) technology, etching to form the microLED column array, and vapor-depositing electrodes to form the LED epitaxial wafer with a P-type electrode and an N-type electrode;
2) applying the isolation layer onto the superlattice epitaxial wafer formed with the microLED column display array until microLED columns are no longer exposed, to obtain a device;
3) forming, by a photolithography process, a hole deep to the microLED columns display array on a surface of the device, and depositing a metal column in the hole as an anode of an LED;
4) peeling off a crystal film formed by the 2D layered material, and transferring the crystal film to the surface of the device; and
5) etching the crystal film to form an array structure corresponding to the microLED column display array, and depositing a source electrode and a drain electrode on two sides of the crystal film, wherein the drain electrode is electrically connected to the metal column deposited in the hole; and
6) preparing a gate dielectric layer and a top-gate electrode in sequence on a surface of the isolation layer, thereby completing the preparation of the device.

10. The monolithically and heterogeneously integrated microLED display chip according to claim 2, wherein the 2D layered material is black phosphorus (BP) or a layered transition metal compound.

11. The monolithically and heterogeneously integrated microLED display chip according to claim 3, wherein the 2D layered material is black phosphorus (BP) or a layered transition metal compound.

12. The monolithically and heterogeneously integrated microLED display chip according to claim 2, wherein the 2D TFT drive array and the microLED column display array are stacked in a staggered manner to avoid blocking light emitted by the microLED column display array.

13. The monolithically and heterogeneously integrated microLED display chip according to claim 3, wherein the 2D TFT drive array and the microLED column display array are stacked in a staggered manner to avoid blocking light emitted by the microLED column display array.

14. The preparation method according to claim 8, wherein the 2D TFT sequentially comprises the following parts from bottom to top:
the back-gate electrode;
the gate dielectric layer;
the channel layer made of the 2D layered material; and
the source electrode and the drain electrode located on two sides of the channel layer, wherein the metal column connected to a microLED column is connected to the drain electrode.

15. The preparation method according to claim 8, wherein the 2D layered material is black phosphorus (BP) or a layered transition metal compound.

16. The preparation method according to claim 15, wherein the 2D layered material is MoS₂ or WS₂.

17. The preparation method according to claim 15, wherein the isolation layer is an insulating dielectric layer.

18. The preparation method according to claim 8, wherein the 2D TFT drive array and the microLED column display array are stacked in a staggered manner to avoid blocking light emitted by the microLED column display array.

19. The preparation method according to claim 9, wherein the 2D TFT sequentially comprises the following parts from bottom to top:
the channel layer made of the 2D layered material;
the source electrode and the drain electrode located on two sides of the channel layer, wherein the metal column connected to a microLED column is connected to the drain electrode;
the gate dielectric layer; and
the top-gate electrode.

20. The preparation method according to claim 9, wherein the 2D layered material is black phosphorus (BP) or a layered transition metal compound.
